(19) United States
(12) Patent Application Publication
(10) Pub. No.: US 2017/0194174 A1
(43) Pub. Date: Jul. 6, 2017

(54) QUAD CHAMBER AND PLATFORM HAVING MULTIPLE QUAD CHAMBERS

(71) Applicant: Applied Materials, Inc., Santa Clara, CA (US)

(72) Inventors: Karthik JANAKIRAMAN, San Jose, CA (US); Juan Carlos ROCHA-ALVAREZ, San Carlos, CA (US); Hari K. PONNEKANTI, San Jose, CA (US); Mukund SRINIVASAN, Fremont, CA (US)

(21) Appl. No.: 15/388,149

(22) Filed: Dec. 22, 2016

Related U.S. Application Data
(60) Provisional application No. 62/273,285, filed on Dec. 30, 2015.

(51) Int. Cl. H01L 21/67; H01J 37/32; H01L 21/677; H01L 21/683; H01L 23/552

(52) U.S. Cl. CPC H01L 21/67225; H01L 21/6833; H01L 23/552; H01L 21/67766; H01J 37/32082; H01J 37/32449; H01J 37/32532; H01J 37/32715; H01J 2237/334

(57) ABSTRACT

A method and apparatus for processing substrates includes a chamber defining a plurality of processing regions, a heater disposed centrally within each pair of processing regions, each heater having a first major surface and a second major surface opposing the first major surface, each of the first major surfaces defining a first substrate receiving surface and each of the second major surfaces defining a second substrate receiving surface, and a showerhead positioned in an opposing relationship to each of the first substrate receiving surfaces and each of the second substrate receiving surfaces of the heaters.

### BACKGROUND

Field

Embodiments of the disclosure generally relate to semiconductor substrate processing, and more particularly, to etch and plasma related semiconductor substrate manufacturing processes and related hardware.

Description of the Related Art

A chip manufacturing facility is composed of a broad spectrum of technologies. Cassettes containing semiconductor substrates (e.g., wafers) are routed to various stations in a facility where they are either processed or inspected. Semiconductor processing generally involves the deposition of material onto and removal (“etching” and/or “planarizing”) of material from substrates. Typical processes include chemical vapor deposition (CVD) plasma enhanced CVD (PECVD), physical vapor deposition (PVD), electroplating, chemical mechanical planarization (CMP), etching, among others.

One concern in semiconductor processing is substrate throughput. Generally, the greater the substrate throughput, the lower the manufacturing cost and therefore the lower the cost of the processed substrates. In order to increase substrate processing throughput, conventional batch processing chambers have been developed. Batch processing allows several substrates to be processed simultaneously using common fluids, such as process gases, chambers, processes, and the like, thereby decreasing equipment costs and increasing throughput. Ideally, batch-processing systems expose each of the substrates to an identical process environment whereby each substrate simultaneously receives the same process gases and plasma densities for uniform processing of the batch. Unfortunately, the processing within batch processing systems is hard to control such that uniform processing occurs with respect to every substrate. Consequently, batch processing systems are notorious for non-uniform processing of substrates. To achieve better process control, single chamber substrate processing systems were developed to conduct processing on a single substrate in a one-at-a-time-type fashion within an isolated process environment. Unfortunately, single chamber substrate processing systems generally are not able to provide as high a throughput rate as batch processing systems, as each substrate must be sequentially processed.

Therefore, there is a need for a substrate processing system configured to provide controllable uniformity of a single substrate system and improved throughput characteristics of a batch processing system.

### SUMMARY

Embodiments of the disclosure generally provide a substrate processing system having one or more chambers, each chamber capable of processing four substrates. The one or more chambers comprise a plurality of processing regions, and a heater is disposed centrally within each of the processing regions. Each heater includes a disk-shaped member having a first major surface and a second major surface opposing the first major surface. Each of the first major surfaces define a first substrate receiving surface and each of the second major surfaces define a second substrate receiving surface. Each heater may be an electrostatic chuck or a vacuum chuck configured to chuck a substrate to the major surfaces thereof. Each heater may be an electrode for RF plasma generation within the respective chambers. Each chamber includes two showerheads configured to flow precursor gases toward substrates positioned on the respective heaters, which are positioned between the showerheads. In some embodiments, heaters in each dual processing zone function as a single electrode that interacts with two showerheads. Each heater is fixed relative to the chambers but the showerheads may move relative to the heater in each chamber. Substrates may be transferred into or out of the processing regions by a robot blade configured to grip an edge of a substrate or a major surface of the substrate utilizing electrostatic attraction.

A method and apparatus for processing substrates is disclosed and may include a chamber defining a plurality of processing regions, a heater disposed centrally within each pair of processing regions, each heater having a first major surface and a second major surface opposing the first major surface, each of the first major surfaces defining a first substrate receiving surface and each of the second major surfaces defining a second substrate receiving surface, and a showerhead positioned in an opposing relationship to each of the first substrate receiving surfaces and each of the second substrate receiving surfaces of the heaters.

In another embodiment, a quad processing chamber system is provided and includes a first quad processing chamber defining a first plurality of isolated processing regions, comprising a first substrate support and a second substrate support positioned in the first quad processing chamber, a first gas distribution assembly disposed at an upper end and a lower end of a first processing region and a second processing region of the plurality of isolated processing regions, and a second gas distribution assembly disposed at an upper end and a lower end of a third processing region and a fourth processing region of the plurality of isolated processing regions, wherein each of the gas distribution assemblies are independently movable relative to the respective substrate support.

### BRIEF DESCRIPTION OF THE DRAWINGS

So that the manner in which the above recited features of the disclosure are attained can be understood in detail, a more particular description of the disclosure, briefly summarized above, may be had by reference to the embodiments thereof, which are illustrated in the appended drawings. It is to be noted, however, that the appended drawings illustrate only typical embodiments of this disclosure, and are therefore, not to be considered limiting of its scope, for the disclosure may admit to other equally effective embodiments.

FIGS. 1A and 1B illustrate plan views of opposing sides of an exemplary quad chamber system.

FIG. 2 illustrates a perspective view of the exemplary quad chamber system of FIGS. 1A and 1B.

FIG. 3A is a side cross-sectional view of one embodiment of a quad processing chamber that may be used in the system of FIGS. 1A and 1B.

FIG. 3B is a perspective cross-sectional view of a portion of the quad processing chamber of FIG. 3A.

FIG. 4 is a perspective view of one embodiment of a substrate support member that may be used in the transfer chamber of FIGS. 1A and 1B.

FIGS. 5A and 5B are various views of a processing chamber showing one example of a substrate transfer process.

FIGS. 6A-6D are various views of a processing chamber showing another example of a substrate transfer process.

To facilitate understanding, common words have been used, where possible, to designate identical elements that are common to the figures. It is contemplated that elements disclosed in one embodiment may be beneficially utilized on other embodiments without specific recitation.

### DETAILED DESCRIPTION

Embodiments of the disclosure generally provide a plasma processing system adapted to concurrently process multiple substrates. The substrate processing system is configured to combine the advantages of single substrate process chambers and multiple substrate handling for high quality substrate processing, high substrate throughput and a reduced system footprint.

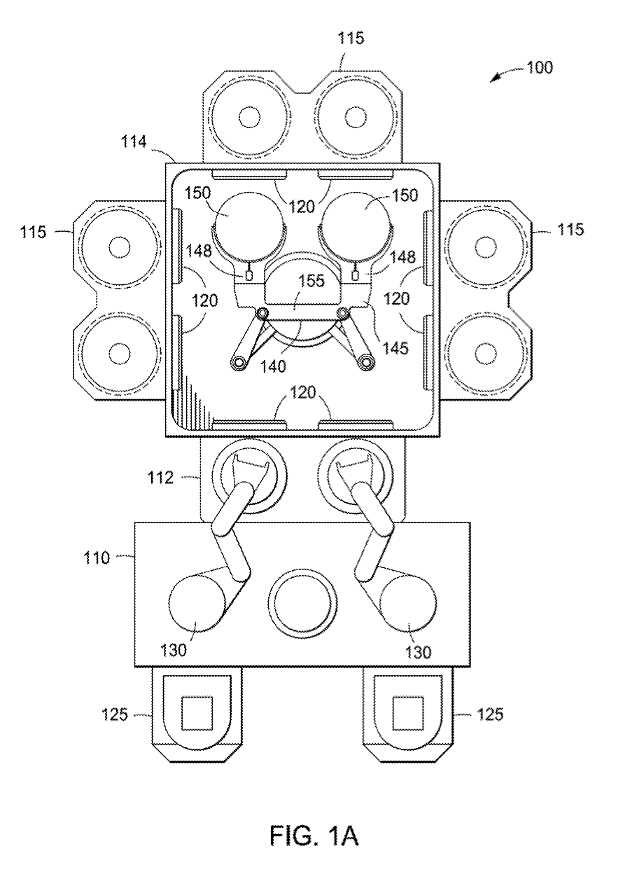

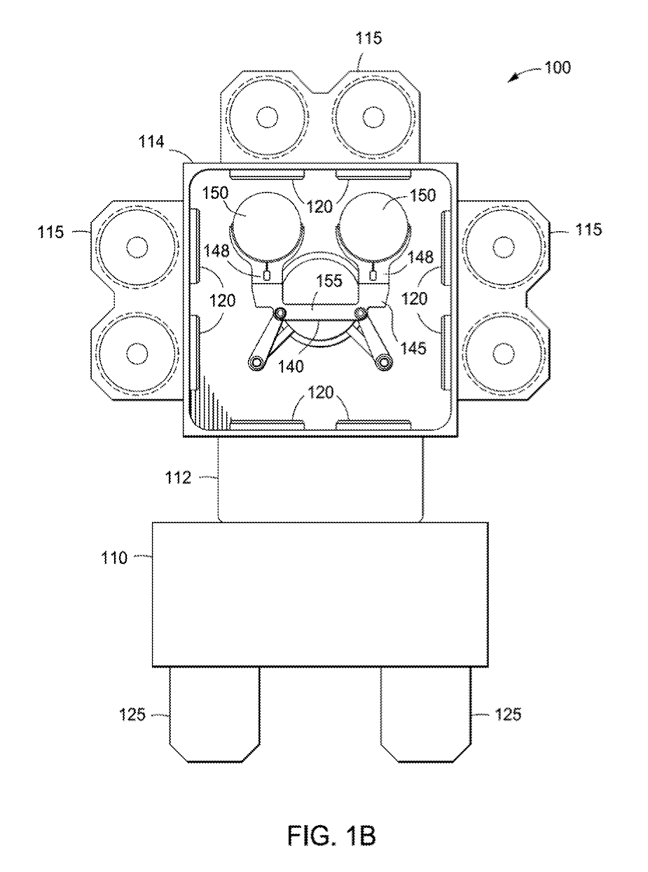

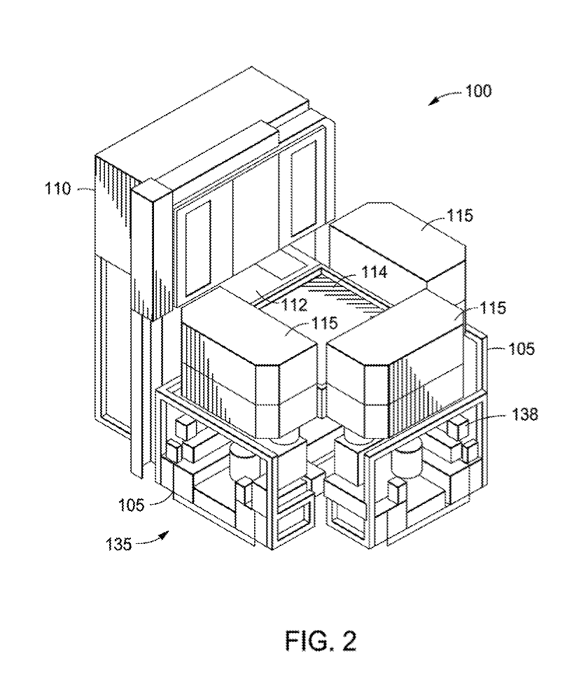

FIGS. 1A and 1B illustrate upper and lower plan views, respectively, and FIG. 2 illustrates a perspective view of an exemplary quad chamber system 100. The system 100 may be used to perform deposition processes, etch processes, annealing processes or other thermal processes, or combinations thereof. The system 100 is generally self-contained having the necessary processing utilities supported on a mainframe structure 105 (shown in FIG. 2). The system 100 can be easily installed and provides a quick start up for operation.

The system 100 generally includes four different regions, namely, a front-end staging area 110, a load lock chamber 112, and a transfer chamber 114 in communication with a plurality of quad processing chambers 115 through isolation valves 120. Each of the quad processing chambers 115 may be configured to process four substrates simultaneously or near simultaneously, such that the system 100 may process twelve substrates simultaneously or near simultaneously.

The front-end staging area 110, which is generally known as a factory interface or mini environment, generally includes an enclosure having at least one substrate containing cassette 125 positioned in communication therewith via a pod loader, for example. The system 100 may also include one or more front-end substrate transfer robots 130, which may generally be single-arm robots configured to move substrates between the front-end staging area 110 and the load lock chamber 112. The front-end substrate transfer robots 130 are generally positioned proximate to cassettes 125 and are configured to remove substrates therefrom for processing, as well as position substrates therein once processing of the substrates is complete.

The front-end staging area 110 is selectively in communication with the load lock chamber 112 through, for example, a selectively actuated valve (not shown). Additionally, load lock 112 may also be selectively in communication with the transfer chamber 114 via another selectively actuated valve, for example. Therefore, the load lock chamber 112 may operate to isolate the interior of the substrate transfer chamber 114 from the interior of the front-end staging area 110 during the process of transferring one or more substrates into the transfer chamber 114 for processing. The load lock chamber 112 may be a side-by-side substrate type chamber, a single substrate type chamber, or multi-substrate-type loadlock chamber, for example, as is generally known in the art.

The system 100 includes a utility supply unit 135 (shown in FIG. 2), which may be positioned in any location that is generally proximate to system 100. However, to maintain a smaller footprint, the utility supply unit 135 may be disposed below the load lock chamber 112. The utility supply unit 135 generally houses the support utilities needed for operation of system 100, such as a gas panel, a power distribution panel, power generators, and other components used to support semiconductor etch processes. The utility supply unit 135 generally includes RF power, bias power, and electrostatic power sections for each quad processing chamber 115.

The system 100 may include a process controller 138 in order to control one or more substrate processing functions. In one embodiment, the process controller 138 includes a computer or other controller adapted to analyze and display data input/output signals of the system 100. The process controller 138 may display the data on an output device such as a computer monitor screen. In general, the process controller 138 includes a controller, such as programmable logic controller (PLC), computer, or other microprocessor-based controller. The process controller 138 may include a central processing unit (CPU) in electrical communication with a memory, wherein the memory contains a substrate processing program that, when executed by the CPU, provides control for at least a portion of the system 100. As such, the process controller 138 may receive inputs from the various components of the system 100 and generate control signals that may be transmitted to the respective components of the system 100 for controlling the operation thereof.

As illustrated in FIG. 1A, a substrate transfer robot 140 may be centrally positioned in the upper interior portion of the transfer chamber 114. The substrate transfer robot 140 is generally configured to receive substrates from the load lock chamber 112 and transport the substrates received therefrom to one of the quad processing chambers 115 positioned about the perimeter of the transfer chamber 114. Additionally, the substrate transfer robot 140 is generally configured to transport substrates between the respective quad processing chambers 115, as well as from the quad processing chambers 115 back into the load lock chamber 112. The substrate transfer robot 140 generally includes a single quad-blade 145 having four substrate support members 148 configured to support up to four substrates 150 thereon simultaneously (only two are shown in FIGS. 1A and 1B). For example, the blade 145 may include two substrate support members 148 that are stacked vertically, and each of the two substrate support members 148 are generally aligned in a respective horizontal plane. The substrate support members 148 may have an edge grip configuration to hold the substrates 150 thereon. Additionally, the blade 145 of the substrate transfer robot 140 is selectively extendable, while the base is rotatable, which may allow the blade access to the interior portion of any of the quad processing chambers 115, the load lock chamber 112, and/or any other chamber positioned around the perimeter of the transfer chamber 114.

As illustrated in FIG. 1B, a substrate transfer robot 140 may be centrally positioned in the lower interior portion of the transfer chamber 114. The substrate transfer robot 140 is generally configured to receive substrates from the load lock chamber 112 and transport the substrates received therefrom to one of the quad processing chambers 115 positioned about the perimeter of the transfer chamber 114. Additionally, the substrate transfer robot 140 is generally configured to transport substrates between the respective quad processing chambers 115, as well as from the quad processing chambers 115 back into the load lock chamber 112. The substrate transfer robot 140 generally includes a single quad-blade 145 having four substrate support members 148 configured to support up to four substrates 150 thereon simultaneously (only two are shown in FIG. 1B). For example, the blade 145 may include two substrate support members 148 that are stacked vertically, and each of the two substrate support members 148 are generally aligned in a respective horizontal plane. The substrate support members 148 may have an edge grip configuration to hold the substrates 150 thereon. Additionally, the blade 145 of the substrate transfer robot 140 is selectively extendable, while the base is rotatable, which may allow the blade access to the interior portion of any of the quad processing chambers 115, the load lock chamber 112, and/or any other chamber positioned around the perimeter of the transfer chamber 114.

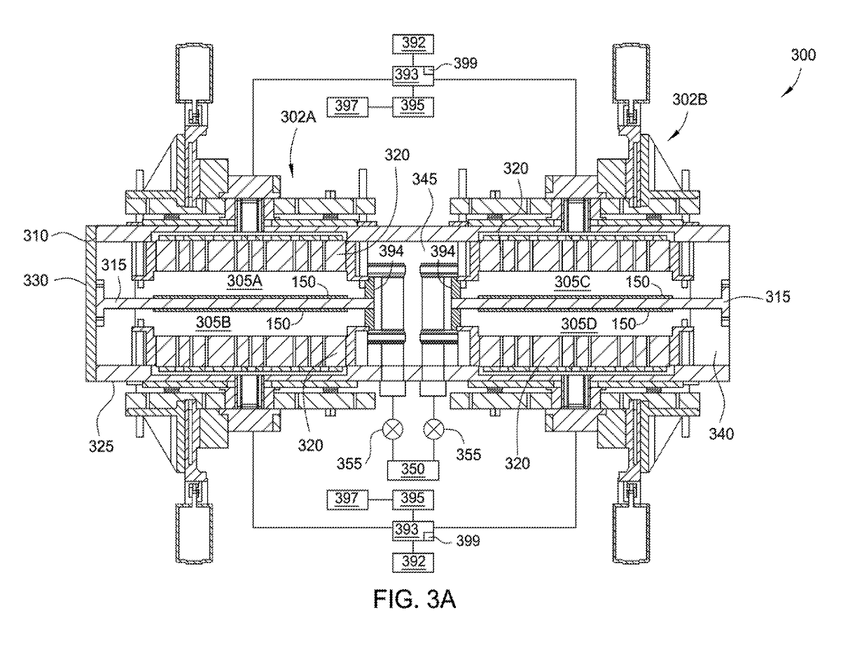

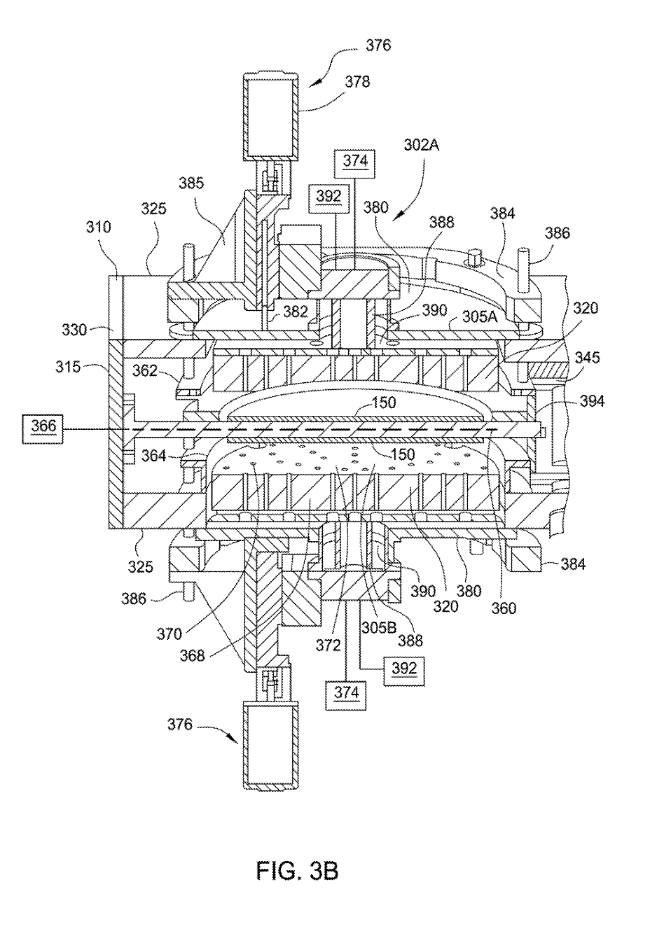

FIGS. 3A and 3B are various views of one embodiment of a quad processing chamber 300 that may be utilized as one or more of the quad processing chambers 115 of FIGS. 1A, 1B, and 2. FIG. 3A is a side cross-sectional view of the quad processing chamber 300 and FIG. 3B is a perspective cross-sectional view of a portion of the quad processing chamber 300 of FIG. 3A.

The quad processing chamber 300 includes a first processing chamber 302A coupled to a second processing chamber 302B, and each the first processing chamber 302A and the second processing chamber 302B are configured to process two substrates 150 simultaneously or near simultaneously. The first processing chamber 302A and the second processing chamber 302B may be operated in parallel such that up to four substrates will be processed similarly in the same amount of time. Thus, the quad processing chamber 300 increases throughput by at least a factor of 2, while minimally increasing footprint of a system such as the system 100 of FIGS. 1A, 1B, and 2.

The quad processing chamber 300 includes a plurality of process volumes 305A-305D contained within a chamber body 310. The quad processing chamber 300 includes two substrate supports 315, each of which may support two substrates 150 thereon on major surfaces thereof. Each of the process volumes 305A and 305B share one of the substrate supports 315, and each of the process volumes 305C and 305D share another one of the substrate supports 315. The quad processing chamber 300 includes four gas distribution plates or showerheads 320. Each of the showerheads 320 are disposed in a respective process volume 305A-305D. The chamber body 310 includes a lid plates 325 and walls 330 that contains the process volumes 305A-305D. In some embodiments, the lid plates 325 may be hinged such that the showerheads 320 may be positioned away from the substrate supports 315 in a clamshell manner to facilitate substrate transfer. A pumping channel 340 at least partially surrounds the process volumes 305A-305D. The pumping channel 340 may be symmetrical about the circumference of the dual process volumes 305A and 305B as well as the dual process volumes 305C and 305D. The pumping channel 340 is in fluid communication with the process volumes 305A-305D and a central channel 345 that is coupled to a vacuum pump 350. Pumping may be circumferential from the outside of the faceplate of the showerheads 320 but through a labyrinth structure such that deposition in or on the faceplate and/or openings in the showerheads 320 does not fall onto the substrates 150.

One or more valves 355 may control a conductance path within the dual process volumes 305A and 305B as well as the dual process volumes 305C and 305D. While the quad processing chamber 300 is shown in an orientation to process the substrates 150 in a horizontal plane, the chamber body 310 may be oriented such that the substrates 150 are processed vertically.

Also shown in FIG. 3A is a process gas supply 392 that provides precursor gases to each of the process volumes 305A-305D. The process gas supply 392 may be coupled to a gas flow splitting device 393 configured to control gas flow to each of the process volumes 305A-305D. In some embodiments, the gas flow splitting device 393 includes a gas flow controller 395 and/or a gas flow meter 397. The gas flow meter 397 and the gas flow controller 395 may be used to control the gas flow between each of the plurality of processing regions (e.g., process volumes 305A-305D). In some embodiments, the gas flow splitting device 393 comprises a flow resistive element 399 to provide a substantially equal gas flow to each of the plurality of processing regions (e.g., process volumes 305A-305D).

In FIG. 3B, the first processing chamber 302A of the quad processing chamber 300 is described in more detail. However, the second processing chamber 302B may be configured similarly to the first processing chamber 302A.

The substrate support 315 may be fixed to the wall 330 of the chamber body 310 by fasteners (not shown) in a cantilevered manner, in one embodiment. In some embodiments, the substrate support 315 bifurcates the first processing chamber 302A such that the process volumes 305A and 305B are substantially equal in size. The substrate support 315 includes a first major surface 362 and an opposing second major surface 364, each of which configured to receive and secure a substrate 150 thereon.

In one aspect, the substrate support 315 includes a heater 360. Alternatively or additionally, the substrate support 315 is coupled to a power supply 366 to function as an electrostatic chuck. In one example, the substrate support 315 is a bi-polar chuck that selectively chucks the substrates 150 on the respective first major surface 362 and second major surface 364. In other embodiments, the substrate support 315 may be a heated vacuum chuck that selectively chucks the substrates 150 on the respective first major surface 362 and second major surface 364. The process controller 138 (shown in FIG. 1B) may be coupled to the quad processing chamber 300 (shown in FIG. 3A) in order to control substrate processing parameters in the respective process volumes 305A-305D (shown in FIG. 3A). The process controller 138 may be utilized to control RF power and/or tuning thereof to each of the process volumes 305A-305D. For example, the process controller 138 may be a RF tuning device that may be utilized to lock output signals of the RF power supplies (e.g., power supply 374 shown in FIG. 3B). The process controller 138 may also be utilized to lock the output frequency of each of the RF power supplies using at least one of a phase lock and a frequency lock. The process controller 138 may be utilized to control actuation of the valves 355. The process controller 138 may also be utilized to control temperature of the substrate supports 315, among other functions.

Each of the showerheads 320 include perforated plates having openings 370 in an output face 372 (e.g., a faceplate). Each of the output faces 372 oppose the first major surface 362 and the second major surface 364 of the substrate support 315. Each of the showerheads 320 may be fabricated from a conductive material, such as a metal, and may function as an electrode within the process volumes 305A and 305B. The showerheads 320 may be coupled to a power supply 374, which may be a radio frequency applicator, and utilized to form a plasma of process gases between the output faces 372 and the substrate support 315. As such, the substrate support 315 may be fabricated from a conductive material to function as an electrode that is shared by the showerheads 320.

Each of the showerheads 320 may be coupled to a translation system 376 that moves the respective perforated plates relative to the first major surface 362 and the second major surface 364 of the substrate support 315. The translation systems 376 may include an actuator 378 that controls a spacing between the output faces 372 and the first major surface 362 and the second major surface 364 of the substrate support 315. In one example, the actuator 378 may be coupled to a lid cover plate 380 by a rod 382. The rod 382 may be a screw-like member that is coupled to a ring 384 which maintains the orientation of the showerheads 320 during movement. For example, the ring 384 may be coupled the actuator 378 by a support member 385, and one or more guide rods 386 interface with the ring 384 during movement of the showerheads 320. The support member 385 may also be coupled with a central shaft 388 that is disposed in an opening 390 in the lid cover plate 380. The central shaft 388 may be fixed to the showerheads 320. The central shaft 388 may also serves as a gas conduit for the showerheads 320 such that gases from the process gas supply 392 may be delivered to the showerheads 320. In some embodiments, the first processing chamber 302A may include a RF shield 394 positioned between the first processing chamber 302A and the second processing chamber 302B (shown in FIG. 3A). The RF shield 394 may include materials adapted to absorb or reflect RF energy. For example, RF shield 299 may include metals such as steel and aluminum, and may also include electromagnetic insulating materials.

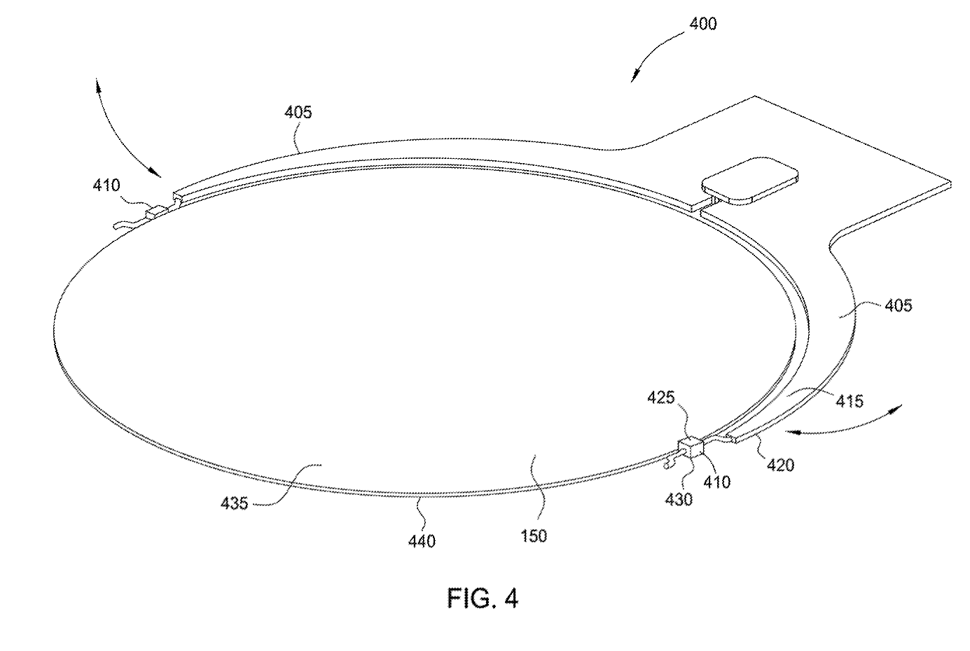

FIG. 4 is a perspective view of one embodiment of a substrate support member 400 that may be used as the substrate support members 148 in the transfer chamber 114 of FIGS. 1A, 1B, and 2. The substrate support member 400 includes support arms 405 each having one or more edge gripping members 410. While only two edge gripping members 410 are shown, the substrate support member 400 may include more edge gripping members 410, such as three edge gripping members 410. One or both of the support arms 405 and the edge gripping members 410 may move laterally in the direction of arrows (toward and away from the edge of the substrate 150). In other embodiments, the edge gripping members 410 may be a clamp device that selectively engages an edge of the substrate 150.

The support arms 405 include a first surface 415 and a second surface 420 opposing the first surface 415. Likewise, the edge gripping members 410 include a first surface 425 and an opposing second surface 430. Depending on whether the substrate support member 400 transfers the substrate 150 to the first major surface 362 or the second major surface 364 of the substrate support 315 (both shown in FIG. 3B), the respective planes of the first surface 415 and the second surface 420, as well as the planes of the first surface 425 and the second surface 430 do not extend beyond a plane of a first major surface 435, or the second major surface 440, of the substrate 150. For example, if the substrate 150 is to be placed or removed from the second major surface 364 of the substrate support 315 shown in FIG. 3B, the first surface 415 of the support arms 405 and the first surface 425 of the edge gripping members 410 are coplanar with, or slightly recessed from (below as shown in FIG. 4), a plane of the first major surface 435 of the substrate 150. In some embodiments (not shown), the first major surface 362 and the second major surface 364 of the substrate support 315 (both shown in FIG. 3B) may include recesses or cut-outs that correspond to the positions of the edge gripping members 410 about a circumference of a substrate 150 receiving surface of the substrate support 315. The recesses or cut-outs are configured to allow space for the edge gripping members 410 to support the substrate 150 when the planes of the first surface 425 and/or the second surface 430 of the edge gripping members 410 is not coplanar with the first major surface 435 or the second major surface 440 of the substrate 150.

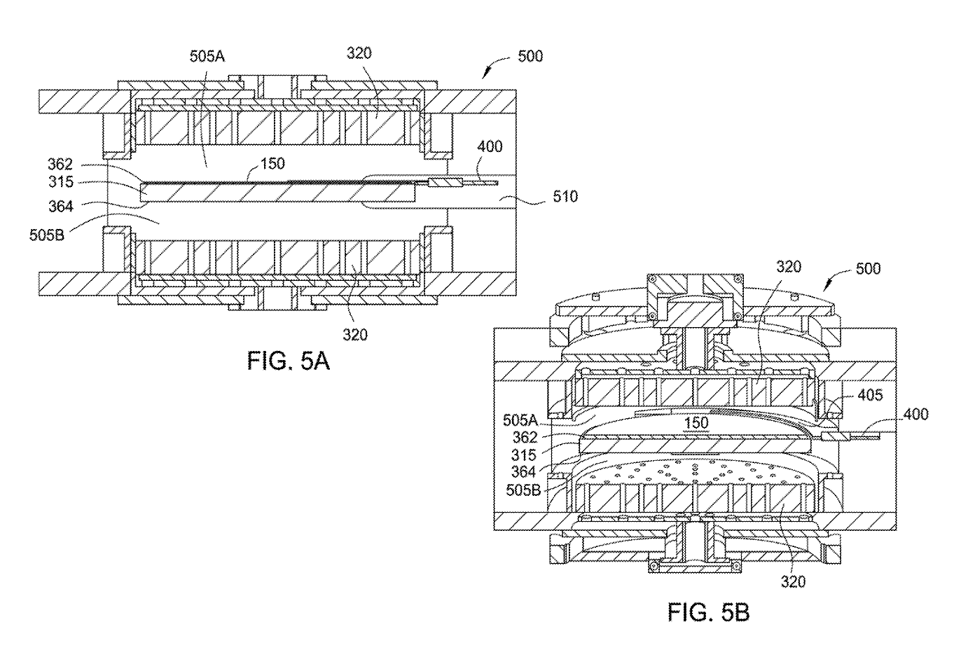

FIGS. 5A and 5B are various views of a processing chamber 500 showing one example of a substrate transfer process using the substrate support member 400 of FIG. 4. The processing chamber 500 may be the first processing chamber 302A or the second processing chamber 302B of the quad processing chamber 115 of FIG. 3A. The processing chamber 500 depicted is a portion of the quad processing chamber 115 of FIG. 3A and includes two process volumes, such as a first process volume 505A and a second process volume 505B. While another processing chamber of the quad processing chamber 115 is not shown, the substrate transfer process described in FIGS. 5A and 5B may be similar and/or occur simultaneously in another processing chamber coupled to the processing chamber 500.

FIG. 5A is a schematic cross-sectional view of the processing chamber 500. FIG. 5B is a schematic isometric cross-sectional view of the processing chamber 500. A substrate 150 is shown on the first major surface 362 of the substrate support 315. The substrate support member 400 is shown extending into the first process volume 505A through a substrate transfer port 510. The support arms 405 (only one is shown in FIG. 5B) surrounds a portion of the peripheral edge of the substrate 150 where the substrate 150 can be gripped.

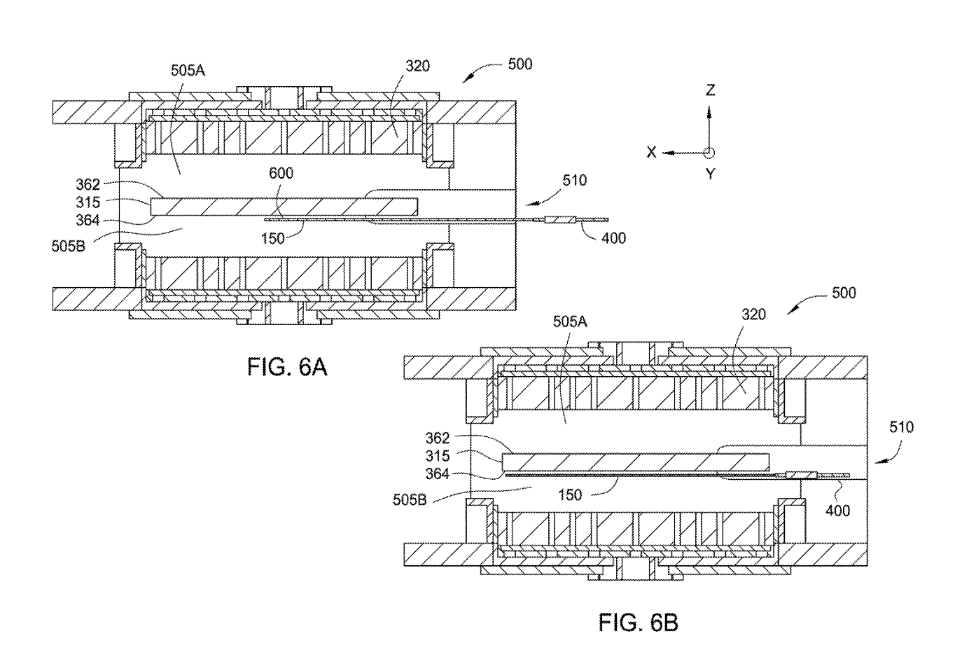

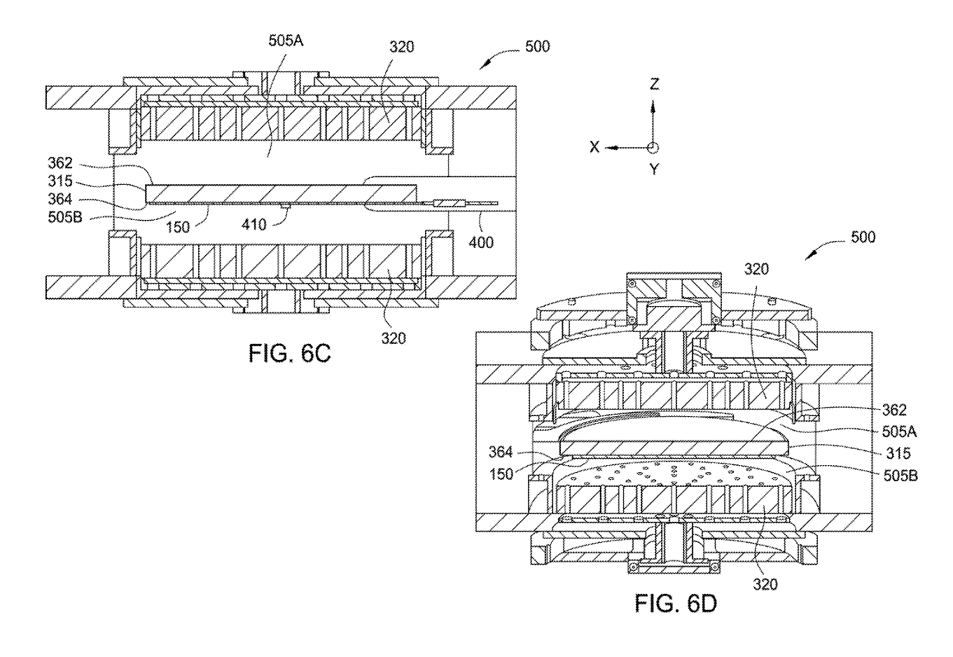

FIGS. 6A-6D are various views of a processing chamber 500 showing another example of a substrate transfer process using the substrate support member 400 of FIG. 4. While another processing chamber of the quad processing chamber 115 of FIG. 3A is not shown, the substrate transfer process described in FIGS. 6A and 6B may be similar and/or occur simultaneously in another processing chamber coupled to the processing chamber 500.

FIGS. 6A and 6B are schematic cross-sectional views of the processing chamber 500 where a substrate 150 is supported on the substrate support member 400. The substrate support member 400 enters the process volume 505B through the substrate transfer port 510 in the X direction as shown. A backside 600 of the substrate 150 is slightly spaced apart from the second major surface 364 of the substrate support 315 (in the Z direction) such that the substrate 150 does not contact the substrate support 315.

FIG. 6C is a schematic cross-sectional view of the processing chamber 500 and FIG. 6D is a schematic isometric cross-sectional view of the processing chamber 500. In FIG. 6C, the substrate support 315 is energized (e.g., electrostatically or applying vacuum) such that the substrate is attracted to the second major surface 364 of the substrate support 315. The edge gripping members 410 (only one is shown) release the substrate 150 and the substrate 150 is effectively clamped onto the second major surface 364 of the substrate support 315 as shown in FIG. 6D. While not shown, a substrate may be transferred to the first major surface 362 of the substrate support 315 simultaneously with the transfer of the substrate 150 onto the second major surface 364. After clamping of the substrate 150, the substrate support member 400 may retract out of the processing chamber 500 via the substrate transfer port 510. The substrate transfer port 510 may be sealed and processing may commence. Additionally, while not shown, substrates for other processing volumes of the quad processing chamber, such as the quad processing chamber 115 of FIG. 3A, may be transferred to all process volumes simultaneously. A transfer process to remove processed substrates from the process volumes may be a substantial reversal of the process described in FIGS. 6A-6D. The removal process may be performed simultaneously.

While the foregoing is directed to embodiments of the disclosure, other and further embodiments of the disclosure may be devised without departing from the basic scope thereof, and the scope thereof is determined by the claims that follow.

1. An apparatus, comprising
a chamber defining a plurality of processing regions, each processing region having a heater disposed centrally within the respective processing regions, each heater having a first major surface and a second major surface facing an opposite direction from the first major surface, each first major surface defining a first substrate receiving surface and each second major surface defining a second substrate receiving surface; and
a showerhead positioned in an opposing relationship to each first substrate receiving surface and each second substrate receiving surface.

2. The apparatus of claim 1, wherein the showerheads are independently movable relative to the substrate receiving surfaces.

3. The apparatus of claim 1, wherein each of the showerheads are coupled to a power supply and each showerhead comprises a first electrode in the processing regions.

4. The apparatus of claim 3, wherein each heater comprises a second electrode.

5. The apparatus of claim 1, wherein each heater comprises an electrostatic chuck.

6. The apparatus of claim 1, wherein each heater comprises a vacuum chuck.

7. The apparatus of claim 1, further comprising:
a radio frequency power supply connected to each showerhead, wherein the output signals of the radio frequency power supplies are locked together; and
each heater includes a bias electrode coupled to a bias power supply.

8. The apparatus of claim 7, further comprising a radio frequency shield member positioned between two showerheads in neighboring processing regions, the radio frequency shield member electro-magnetically isolating the showerheads.

9. The apparatus of claim 7, further comprising a radio frequency power supply controller coupled to the showerheads, for locking the output frequency of each of the RF power supplies using at least one of a phase lock and a frequency lock.

10. The apparatus of claim 1, further comprising a gas flow splitting device in fluid communication with each of the plurality of processing regions.

11. The apparatus of claim 10, wherein the gas flow splitting device comprises at least one resistive element adapted to provide a substantially equal gas flow to each of the plurality of processing regions.

12. The apparatus of claim 10, wherein the gas flow splitting device comprises at least one gas flow controller adapted to provide substantially equal gas flow to each of the plurality of processing regions.

13. The apparatus of claim 10, wherein the gas flow splitting device comprises a gas flow meter and gas flow controller fluidly coupled to a first gas path, wherein the gas flow meter and the gas flow controller are configured to control the gas flow between each of the plurality of processing region.

14. A processing chamber system, comprising:
a first quad processing chamber defining a first plurality of isolated processing regions, comprising:
a first substrate support and a second substrate support positioned in the first quad processing chamber;
a first gas distribution assembly disposed at an upper end and a lower end of a first processing region and a second processing region of the first plurality of isolated processing regions; and
a second gas distribution assembly disposed at an upper end and a lower end of a third processing region and a fourth processing region of the first plurality of isolated processing regions, wherein each of the gas distribution assemblies are independently movable relative to the respective substrate support.

15. The system of claim 14, further comprising:
a second quad processing chamber positioned adjacent the first quad processing chamber, the second quad processing chamber defining a second plurality of isolated processing regions.

16. The apparatus of claim 14, wherein each of the first and second gas distribution assemblies comprises an electrode coupled to a power supply.

17. The apparatus of claim 14, wherein each of the substrate supports comprises a heater.

18. The apparatus of claim 16, further comprising an RF shield between the first and second gas distribution assemblies.

19. The apparatus of claim 17, wherein each of the substrate supports further comprises an electrode.

20. An apparatus, comprising a chamber defining a plurality of processing regions;
at least two heaters disposed centrally within the plurality of processing regions, each heater having a first major surface and a second major surface opposing the first major surface, each first major surface defining a first substrate receiving surface and each second major surface defining a second substrate receiving surface, and each heater including a bias electrode coupled to a bias power supply;
a showerhead positioned in an opposing relationship to each first substrate receiving surface and each second substrate receiving surface, each showerhead independently movable relative to the substrate receiving surfaces; and
a plurality of radio frequency power supplies, one of each connected to each showerhead, wherein the output signals of the radio frequency power supplies are locked together.
